(19) United States
(12) Patent Application Publication
(10) Pub. No.: US 2020/0126899 A1
(43) Pub. Date: Apr. 23, 2020

(54) PRINTED CIRCUIT BOARD AND A SEMICONDUCTOR PACKAGE INCLUDING THE SAME

(71) Applicant: SAMSUNG ELECTRONICS CO., LTD., SUWON-SI (KR)

(72) Inventors: SHLE GE LEE, SEOUL (KR); YOUNG BAE KIM, SEOUL (KR)

(21) Appl. No.: 16/393,041

(22) Filed: Apr. 24, 2019

(30) Foreign Application Priority Data
Oct. 22, 2018 (KR) 10-2018-0125901

(51) Int. Cl. H01L 23/498; H01L 23/15

(52) U.S. Cl. CPC H01L 23/49838; H01L 23/49866; H01L 23/15; H01L 24/16; H01L 23/49827; H01L 23/49822; H01L 23/49816

(57) ABSTRACT

A printed circuit board is provided that includes a base substrate including a pair of first edges extending in a first direction and a pair of second edges extending in a second direction, perpendicular to the first direction. A circuit region including a plurality of circuit patterns is disposed on at least one of a first surface and a second surface of the base substrate. A dummy region including a conductive dummy pattern is disposed on at least one of the first surface and the second surface. The conductive dummy pattern is separated from a boundary of the dummy region, and a maximum length of the conductive dummy pattern in the first or second direction passes through a center of the conductive dummy pattern.

### CROSS-REFERENCE TO RELATED APPLICATION

This application claims priority under 35 U.S.C. § 119 to Korean Patent Application No. 10-2018-0125901 filed on Oct. 22, 2018 in the Korean Intellectual Property Office, the disclosure of which is incorporated by reference herein in its entirety.

### TECHNICAL FIELD

The present inventive concept relates to a printed circuit board and a semiconductor package including the same.

### DESCRIPTION OF RELATED ART

Semiconductor packages include semiconductor chips and printed circuit boards on which the semiconductor chips are mounted, and such printed circuit boards may include a circuit pattern for transmitting signals of the semiconductor chips. A printed circuit board includes a base substrate having insulating properties, and a circuit pattern formed on the base substrate. Warping of the printed circuit board may unintentionally occur due to heat generated during operations of the semiconductor chip, or force or heat applied in a manufacturing process of a semiconductor package.

### SUMMARY

According to an exemplary embodiment of the present inventive concept, a printed circuit board is provided that includes a base substrate including a pair of first edges extending in a first direction and a pair of second edges extending in a second direction that is perpendicular to the first direction. A circuit region including a plurality of circuit patterns is disposed on at least one of a first surface and a second surface of the base substrate. A dummy region including a conductive dummy pattern is disposed on at least one of the first surface and the second surface. The conductive dummy pattern is separated from a boundary of the dummy region, and a maximum length of the conductive dummy pattern in the first or second direction passes through a center of the conductive dummy pattern.

According to an exemplary embodiment of the present inventive concept, a semiconductor package includes a printed circuit board including a circuit region having a plurality of circuit patterns, and a dummy region including a conductive dummy pattern separated from the plurality of circuit patterns. The printed circuit board includes a first edge extending in a first direction and a second edge extending in a second direction, perpendicular to the first direction. A semiconductor chip is mounted on the printed circuit board and connected to the plurality of circuit patterns. The conductive dummy pattern is separated from a boundary between the circuit region and the dummy region, and a maximum length of the conductive dummy pattern in the first direction passes through a center of the conductive dummy pattern.

According to an exemplary embodiment of the present inventive concept, a semiconductor package is provided including a printed circuit board including a plurality of circuit patterns and a conductive dummy pattern separated from the plurality of circuit patterns. The conductive dummy pattern has a rhombic shape or a cross shape and is at least partially surrounded by a solder resist layer. A semiconductor chip is mounted on the printed circuit board and connected to the plurality of circuit patterns. A length of the conductive dummy pattern in a first direction parallel to an edge of the printed circuit board has a maximum value passing through a center of the conductive dummy pattern.

### BRIEF DESCRIPTION OF THE DRAWINGS

The above and other features of the present inventive concept will be more clearly understood by describing in detail exemplary embodiments thereof with reference to the accompanying drawings, in which:

FIG. 1 is a perspective view illustrating a printed circuit board according to an exemplary embodiment of the present inventive concept;

FIG. 2 is a side view illustrating a cross-section of a printed circuit board according to an exemplary embodiment of the present inventive concept;

FIG. 3 is a plan view illustrating an upper surface of a printed circuit board according to an exemplary embodiment of the present inventive concept;

FIG. 4 is a plan view of a lower surface of a printed circuit board according to an exemplary embodiment of the present inventive concept;

FIG. 5 is an enlarged plan view illustrating region A of a dummy region of a printed circuit board according to an exemplary embodiment of the present inventive concept;

FIGS. 6A, B, C, and D illustrate conductive dummy patterns included in a printed circuit board according to exemplary embodiments of the present inventive concept;

FIG. 7 is a graph illustrating an effect of a conductive dummy pattern of a printed circuit board according to an exemplary embodiment of the present inventive concept;

FIG. 8 is an enlarged plan view illustrating region A of a dummy region of a printed circuit board according to an exemplary embodiment of the present inventive;

FIG. 9 is an enlarged plan view illustrating a conductive dummy pattern according to an exemplary embodiment of the present inventive concept;

FIG. 10 is an enlarged plan view illustrating region A of a dummy region of a printed circuit board according to an exemplary embodiment of the present inventive concept;

FIG. 11 is a cross-sectional view illustrating a semiconductor package according to an exemplary embodiment of the present inventive concept;

FIG. 12 is an enlarged view of a dummy region of a printed circuit board according to an exemplary embodiment of the present inventive concept;

FIG. 13 is an enlarged view of a dummy region included in a semiconductor package according to an exemplary embodiment of the present inventive concept;

FIG. 14 is a cross-sectional view illustrating a semiconductor package according to an exemplary embodiment of the present inventive concept; and

FIG. 15 is a plan view illustrating a portion of layers of a semiconductor package according to an exemplary embodiment of the present inventive concept.

### DETAILED DESCRIPTION OF THE EMBODIMENTS

Hereinafter, exemplary embodiments of the present inventive concept will be described with reference to the accompanying drawings.

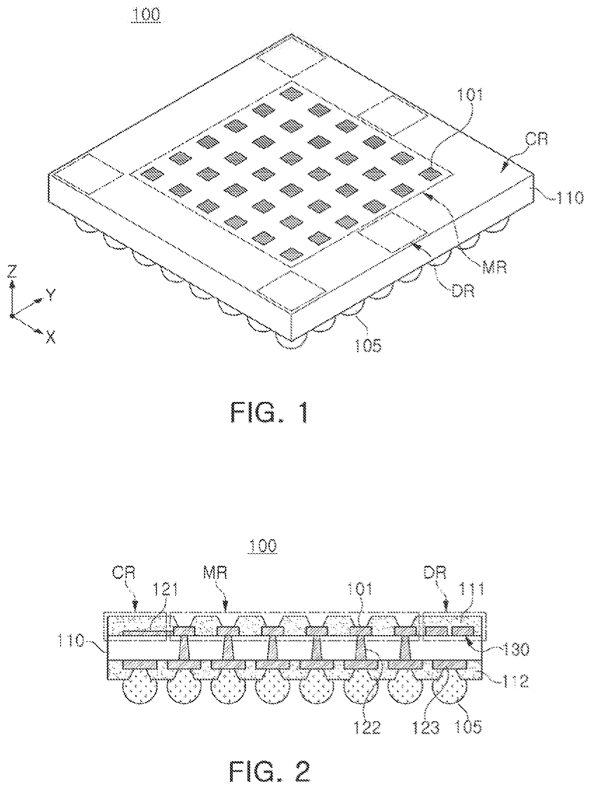

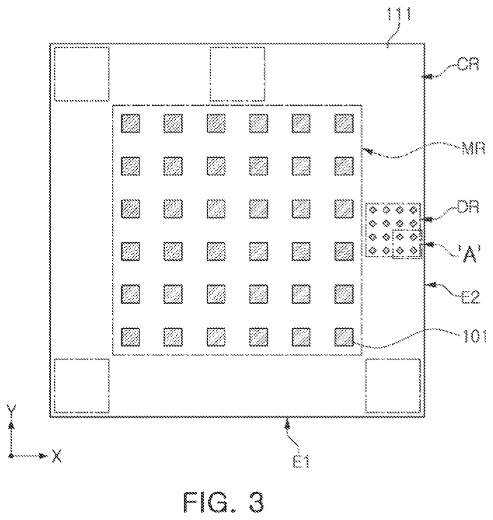

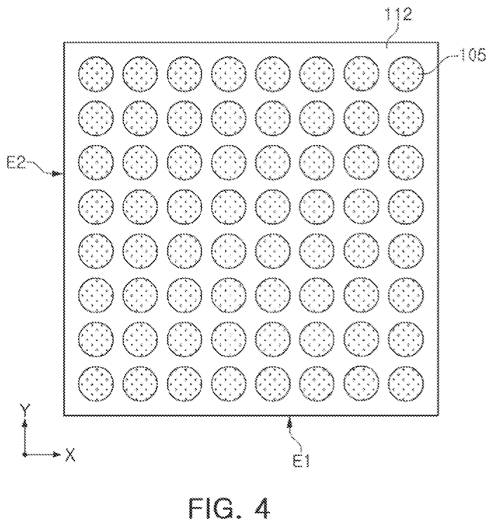

FIG. 1 is a perspective view illustrating a printed circuit board according to an exemplary embodiment of the present inventive concept. FIG. 2 is a side view illustrating a printed circuit board according to an exemplary embodiment of the present inventive concept. FIG. 3 is a top plan view illustrating a printed circuit board according to an exemplary embodiment of the present inventive concept. FIG. 4 is a bottom plan view of a printed circuit board according to an exemplary embodiment of the present inventive concept.

Referring to FIG. 1, a printed circuit board 100 may include a base substrate 110, and a plurality of circuit patterns formed on the base substrate 110. The plurality of circuit patterns may be formed in a circuit region CR to be connected to a plurality of connection pads 101 provided in a mounting region MR. The connection pads 101 may be connected to pads formed on a semiconductor chip via microbumps or the like.

A dummy region DR may be disposed in the circuit region CR and may be a region in which circuit patterns are not formed. However, the inventive concept is not limited thereto. For example, the dummy region DR may be disposed elsewhere on the printed circuit board than that of the circuit region CR. The dummy region DR may have conductive dummy patterns disposed thereon on at least one of an upper surface and a lower surface of the base substrate 110. The conductive dummy patterns may include a predetermined proportion of a conductive metal layer, for example a copper layer. The copper layer may be formed in a predetermined pattern.

A plurality of connection terminals 105 may be disposed on a lower surface of the base substrate 110. The connection terminals 105 may transmit a signal received from an external device to the semiconductor chip connected to the mounting region MR, or may output a signal output from the semiconductor chip to the external device. The connection terminals 105 and the connection pads 101 may be electrically connected to each other by circuit patterns formed on at least a portion of an upper and lower surface and inside of the base substrate 110.

Referring to FIG. 2, the plurality of connection pads 101 may be formed on a first surface, for example, an upper surface of the base substrate 110, and the plurality of connection terminals 105 may be formed on a lower surface of the base substrate 110, for example, on a second surface. According to an exemplary embodiment of the present inventive concept, the size of each of the connection terminals 105 may be greater than the size of each of the connection pads 101. The connection pads 101 and the connection terminals 105 may be electrically connected to each other by circuit patterns 121, 122 and 123 formed on the first surface and the second surface and inside of the base substrate 110. The circuit patterns 121, 122 and 123 may include vias 122, redistribution wiring patterns 123, and the like.

Conductive dummy patterns 130 formed in the dummy region DR may be formed on at least one of the first surface and the second surface of the base substrate 110. The conductive dummy patterns 130 are illustrated as being formed on the first surface of the base substrate 110 in the exemplary embodiment illustrated in FIG. 2, but may also be formed on the second surface. A plurality of the conductive dummy patterns 130 may be formed in the dummy region DR, and may be separated from each other by a first solder resist layer 111 formed on the first surface of the base substrate 110. A second solder resist layer 112 may be formed on the second surface of the base substrate 110 to protect the redistribution wiring pattern 123 and the connection terminals 105.

The conductive dummy patterns 130 may be provided to significantly reduce deformation of the printed circuit board 100 due to heat or external force generated during operations and/or manufacturing of a semiconductor package including the printed circuit board 100. In an example, the base substrate 110 of the printed circuit board 100 may include a flame retardant (FR4) material formed of a glass fiber, and the FR4 material has anisotropic properties. For example, in the exemplary embodiment of the inventive concept illustrated in FIGS. 1 and 2, degrees of modulus, thermal expansion coefficients, rigidity, and the like of the base substrate 110 may be different in an X axis direction from a Y axis direction.

In an exemplary embodiment of the present inventive concept, the shape and arrangement of the conductive dummy patterns 130 may be determined in consideration of the anisotropic properties of the base substrate 110. In an exemplary embodiment of the present inventive concept, the conductive dummy patterns 130 may be provided in such a manner that a maximum length of each in the X-axis or Y-axis direction passes through a center of each of the conductive dummy patterns. Each of the conductive dummy patterns 130 may have a rhombus, a cross, a hexagonal shape, or the like. To significantly reduce deformation of the base substrate 110 having anisotropic properties, the conductive dummy patterns 130 may be disposed separate from a boundary of the dummy region DR.

Referring to FIG. 3, the first solder resist layer 111 may be formed on the first surface, for example the upper surface of the base substrate 110. The plurality of connection pads 101 may be formed on the mounting region MR. The plurality of conductive dummy patterns 130 may be separated from each other in the dummy region DR. The conductive dummy patterns 130 may have a shape capable of significantly reducing deformation of the base substrate 110 having anisotropic properties, and may be separated from a boundary between the dummy region DR and the circuit region CR. The conductive dummy patterns 130 may be disposed in a lattice form in which they are separately arranged in a plurality of rows and columns. However, the inventive concept is not limited thereto; for example the conductive dummy patterns 130 may be disposed in a staggered arrangement.

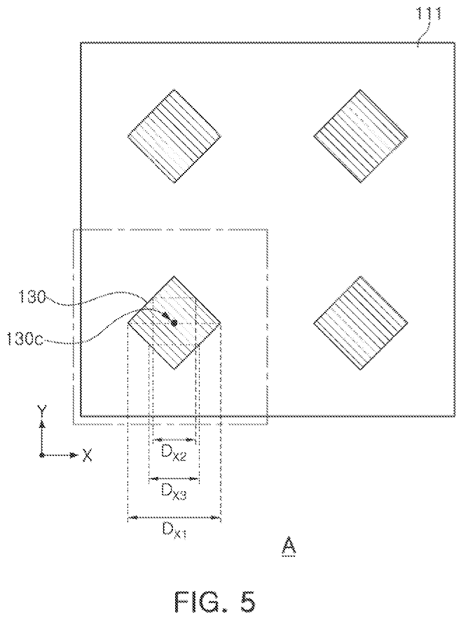

According to an exemplary embodiment of the present inventive concept, the base substrate 110 may include a pair of first edges E1 extending in a first direction (e.g., the X-axis direction) and a pair of second edges E2 extending in a second direction (e.g., the Y-axis direction). The shape of the conductive dummy patterns 130 may satisfy the condition that a maximum length of each of the conductive dummy patterns 130 in the first direction or in the second direction passes through the center of the conductive dummy pattern 130, which will be described in detail with reference to FIG. 5.

Referring to FIG. 4, the second solder resist layer 112 and the connection terminals 105 may be formed on the second surface, for example, on the lower surface of the base substrate 110. As described above with reference to FIG. 2, the plurality of connection pads 101 may be connected to the connection terminals 105 by the circuit patterns 121, 122 and 123.

FIG. 5 is an enlarged view of region A of a dummy region of a printed circuit board according to an exemplary embodiment of the present inventive concept.

Referring to FIG. 5, the conductive dummy patterns 130 may respectively have a rhombic shape, and may be separated from each other by the first solder resist layer 11I. For example, the dummy patterns 130 may be separated from one another at predetermined intervals with a solder resist layer disposed therebetween to at least partially surround the dummy patterns 130. As described above, the conductive dummy patterns 130 may have a maximum length in the first direction (e.g., the X-axis direction) or the second direction (e.g., the Y-axis direction) which passes through a center thereof.

A maximum length of the conductive dummy pattern 130 in the first direction may be defined as D_{X1}, and D_{X1} may pass through a center 130C of the conductive dummy pattern 130 having a rhombic shape. For example, the center 130C may be the center of gravity of the conductive dummy pattern 130. On the other hand, the other lengths D_{X2}, D_{X3}, and the like may be smaller than the maximum length D_{X1} of the conductive dummy pattern 130 in the first direction (e.g., the X-direction) may not pass through the center 130C of the conductive dummy pattern 130.

Among the reasons why the conductive dummy patterns 130 are formed to have such a shape in which maximum lengths of the conductive dummy patterns 130 in the first direction may pass through the center 130C thereof may be due to the anisotropic properties of the base substrate. The base substrate may include an FR4 material formed of a glass fiber, and in this case, degrees of rigidity of the base substrate in the first direction (e.g., the x-direction) and the second direction (e.g., the y-direction) may differ depending on a fiber woven structure included therein. According to exemplary embodiments of the present inventive concept, as the conductive dummy pattern 130 is formed such that a maximum length of the conductive dummy pattern 130 is defined in a position passing through the center of the conductive dummy patter 130 and parallel to the first direction (e.g., the x-direction) or the second direction (e.g., the y-direction), deformation of the printed circuit board due to heat, external force, or the like applied thereto may be significantly reduced.

According to an exemplary embodiment of the present inventive concept, a length of the conductive dummy pattern 130 passing through the center 130C thereof that is not parallel to an axes of the first direction (e.g., the x-direction) or the second direction (e.g., the y-direction) may be less than a maximum length of the conductive dummy pattern 130. When the conductive dummy pattern 130 has a rhombic shape a length of the conductive dummy pattern 130 that is not parallel to the first direction or the second direction, while passing the center 130C may be smaller than the maximum length D_{X1} thereof in the first direction (e.g., the x-direction).

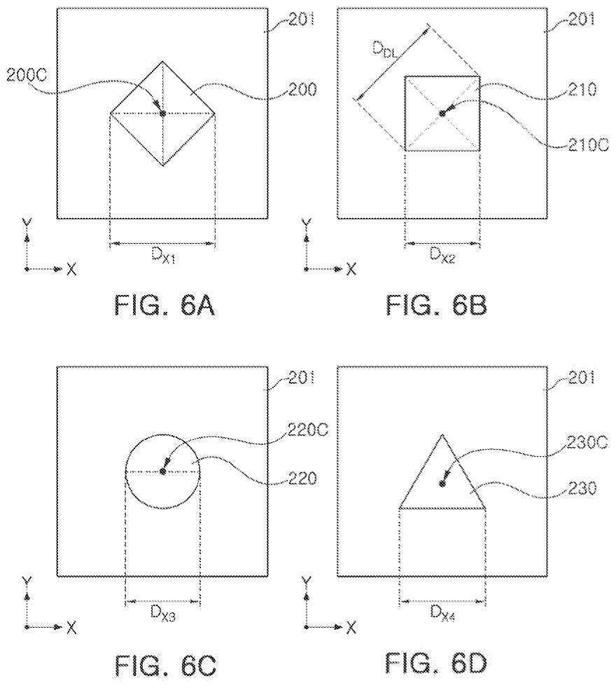

FIGS. 6A, B, C, and D illustrate conductive dummy patterns included in a printed circuit board according to exemplary embodiments of the present inventive concept.

Referring to FIGS. 6A, 6B, 6C, and 6D, conductive dummy patterns 200, 210, 220 and 230, respectively, may feature various shapes and at least partially surrounded by a solder resist layer 201. Among the conductive dummy patterns 200, 210, 220 and 230 illustrated in FIGS. 6A to 6D, respectively, the conductive dummy pattern 200 illustrated in FIG. 6A may satisfy conditions according to exemplary embodiments of the present inventive concept. For example, a maximum length of the conductive dummy pattern 200 in FIG. 6A may correspond to a position passing through a center of the conductive dummy pattern 200 and parallel to a first direction (e.g., a x-direction) or a second direction (e.g., a y-direction). On the other hand, the conductive dummy patterns 210, 220 and 230 illustrated in FIGS. 6B to 6D may not satisfy the conditions according to exemplary embodiments of the present inventive concept.

Referring to FIG. 6A, the conductive dummy pattern 200 has a rhombic shape, and a maximum length D_{X1} may correspond to a line passing through a center 200C thereof and parallel to an axis of the first direction (e.g., the x-direction). Referring to FIG. 6B, the conductive dummy pattern 210 has a square shape, and a maximum length D_{DL} thereof may be defined as a diagonal line of the conductive dummy pattern 210 relative the X and Y axes. According to the exemplary embodiment of FIG. 6B, the maximum length D_{DL} of the conductive dummy pattern 210 may pass through a center 210C of the conductive dummy pattern 210, but may not be parallel to the first direction or the second direction. For example, a length D_{X2} passing the center 210C and parallel to the first direction or the second direction may be smaller than the maximum length D_{DL}.

Referring to FIG. 6C, the conductive dummy pattern 220 may have a circular shape. Thus, a maximum length of the conductive dummy pattern 220 may not be defined exclusively in a direction parallel to the first direction (e.g., the x-direction) or the second direction (e.g., the y-direction), since all the lengths passing through a center 220C of the conductive dummy pattern 220 are the maximum length. In addition, in the exemplary embodiment illustrated in FIG. 6C, a length thereof which is not parallel to the first direction (e.g., the x-direction) or the second direction (e.g., the y-direction), while passing through the center 220C of the conductive dummy pattern 220, may not be smaller than a maximum length D_{X3}, and may be equal to the maximum length D_{X3}. On the other hand, in an exemplary embodiment illustrated in FIG. 6D, the conductive dummy pattern 230 may have an equilateral triangular shape. As illustrated in FIG. 6D, since a maximum length D_{X4} of the conductive dummy pattern 230 in the first direction corresponds to a lower side of a regular triangle, the maximum length D_{X4} of the conductive dummy pattern 230 in the first direction does not pass through a center 230C of the conductive dummy pattern 230.

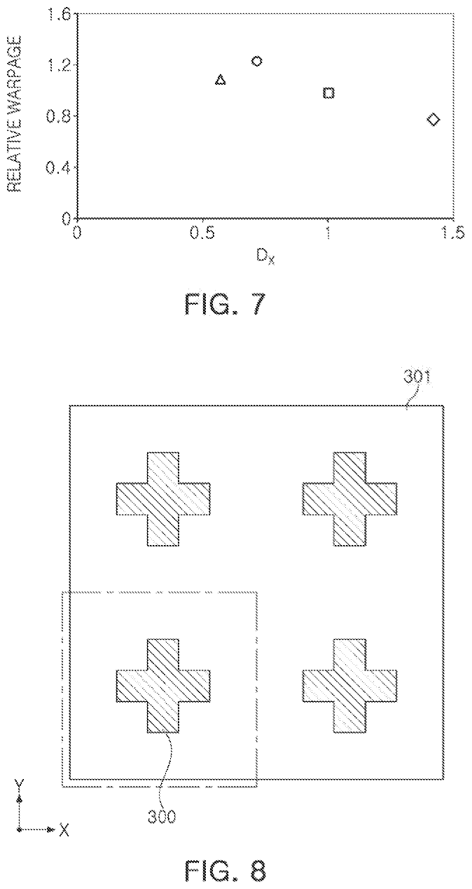

FIG. 7 is a graph illustrating a reduction in warping owing to the conductive dummy patterns 200, 210, 220 and 230 illustrated in FIGS. 6A to 6D. Referring to FIG. 7, in the case of the conductive dummy pattern 200 having a rhombic shape according to the exemplary embodiment illustrated in FIG. 6A, warping of the printed circuit board is reduced as compared with those of the other conductive dummy patterns 210, 220 and 230. For example, heat generated on the printed circuit board is divided into a relatively high temperature and a relatively low temperature (e.g., room temperature), and experimental results based on warping of the printed circuit board on which the conductive dummy patterns illustrated in 6A-D are formed is illustrated in Table 1 below. As can be seen from the following Table 1, warping of the printed circuit board including the rhombic-shaped conductive dummy pattern 200 may be relatively low, as compared with the printed circuit boards including the conductive dummy patterns 210, 220 and 230 having different shapes.

TABLE 1
Magnitude of warping

Shape

| | Square | Triangle | Circle | Rhombus |
|---|---|---|---|---|
| Room | 1 | 1.10 | 1.03 | 0.92 |
| Temperature | | | | |
| High | 1 | 1.25 | 1.10 | 0.8 |
| Temperature | | | | |

However, the shape of the conductive dummy pattern proposed in the exemplary embodiment of the present inventive concept is not necessarily limited to the rhombic shape. As described above, the shape of the conductive dummy pattern proposed by the exemplary embodiment of the present inventive concept may be a shape satisfying the conditions that a maximum length of the conductive dummy pattern passes through the center thereof and is parallel to the first direction (e.g., the x-direction) or the second direction (e.g., the y-direction), and disposed at an edge direction of the base substrate. Thus, in addition to the rhombic shape, the conductive dummy pattern may be formed to have various shapes satisfying the above conditions. In addition, conductive dummy patterns having different shapes may be formed on a single printed circuit board.

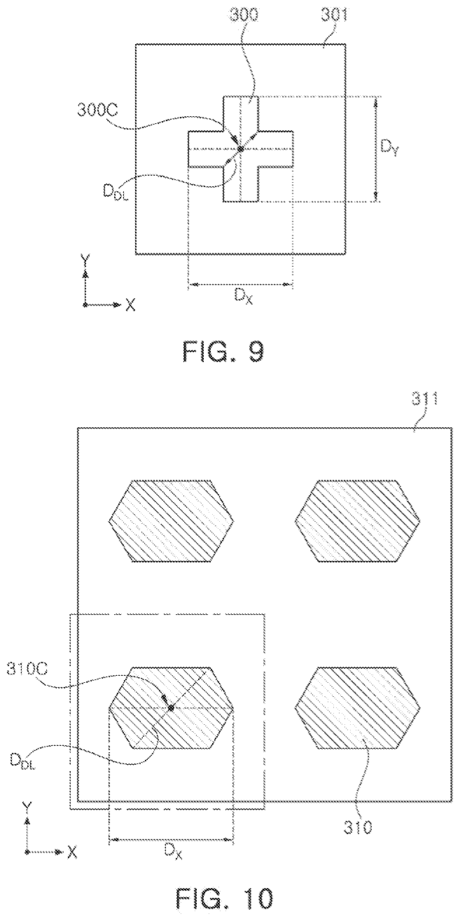

FIG. 8 is an enlarged plan view illustrating region A of a dummy region of a printed circuit board according to an exemplary embodiment of the present inventive. FIG. 9 is an enlarged plan view illustrating a conductive dummy pattern according to an exemplary embodiment of the present inventive concept.

Referring to FIGS. 8 and 9, conductive dummy patterns 300 may have a cross shape, and may be separated from each other by a solder resist layer 301. The conductive dummy patterns 300 may be disposed on an upper surface or a lower surface of a base substrate. According to an exemplary embodiment of the present inventive concept as illustrated in FIG. 8, a first direction (e.g., an x direction) and a second direction (e.g., a y direction) may correspond to edge lengths of the base substrate, respectively.

Referring to FIG. 9, a maximum length D_{X} of the conductive dummy pattern 300 in the first direction may pass through a center 300C of the conductive dummy pattern 300. A maximum length D_{Y} of the conductive dummy pattern 300 in the second direction may also pass through the center 300C of the conductive dummy pattern 300. On the other hand, a length D_{DL}, passing through the center 300C and that is not parallel to the first direction or the second direction may be smaller than each of the maximum length D_{X} and D_{Y} of the conductive dummy pattern 300.

According to an exemplary embodiment of the present inventive concept as illustrated in FIGS. 8 and 9, the conductive dummy pattern 300 is illustrated as having a shape in which the maximum length D_{X} in the first direction and the maximum length D_{Y} in the second direction are the same as each other, but the inventive concept is not limited thereto. For example, the conductive dummy pattern may have a cross shape, while being configured in such a manner that the maximum length D_{X} in the first direction is greater than the maximum length D_{Y} in the second direction, or the maximum length D_{Y} in the second direction may be greater than the maximum length D_{X} in the first direction.

The conductive dummy pattern 300 and the solder resist layer 301 may be formed on an upper surface or a lower surface, of the base substrate. The base substrate may be formed of an FR4 material. Due to anisotropic properties of the FR4 material formed of a glass fiber and having a woven structure, the base substrate may have different degrees of thermal expansion coefficients, modulus, rigidity and the like in the first direction and the second direction parallel to length directions of the edges of the base substrate. In consideration of the anisotropic properties of the base substrate the conductive dummy pattern 300 may be configured in such a manner that the maximum lengths D_{X} and D_{Y} thereof pass through the center 300C, and a length thereof passing through the center 300C in a direction not parallel to the edge directions is smaller than each of the maximum lengths D_{X} and D_{Y}. Thus, deformation of the printed circuit board due to heat and/or external force generated in a manufacturing process of the printed circuit board including a base substrate, or during operation thereof after a semiconductor chip is mounted, may be significantly reduced. This reduction in deformation of the printed circuit board thereby increases a manufacturing yield and the performance of the printed circuit board.

Referring to FIG. 10, conductive dummy patterns 310 disposed in a region A of a dummy region DR of a printed circuit board may have a hexagonal shape, and may be spaced apart from one another. For example, the conductive dummy patterns 310 may be separated from each other by a solder resist layer 311 that at least partially surrounds the conductive dummy patterns 310. Similar to the example embodiments described with reference to FIGS. 8 and 9, the conductive dummy patterns 310 may be disposed on an upper surface or a lower surface of a base substrate, and in the exemplary embodiment of the inventive concept illustrated in FIG. 10, a first direction (e.g., an x-direction) and a second direction (e.g., a y-direction) may correspond to edge directions of the base substrate, respectively. For example, a first direction and a second direction may be parallel to orthogonal sides of a base substrate.

In the exemplary embodiment illustrated in FIG. 10, a maximum length D_{X} of the conductive dummy pattern 310 may be parallel to the first direction (e.g., an x-direction), and may pass through a center 310C. In the exemplary embodiment illustrated in FIG. 10, the maximum length D_{X} of the conductive dummy pattern 310 may be defined in the first direction. In addition, another length D_{DL} in a diagonal direction, which may be defined in the conductive dummy pattern 310, may be smaller than the maximum length D_{X}. For example, the length DD, passing through the center 310C is not parallel to the first direction or the second direction, and may be smaller than the maximum length D_{X}. According to an exemplary embodiment of the present inventive concept the conductive dummy pattern 310 may not have a regular hexagonal shape.

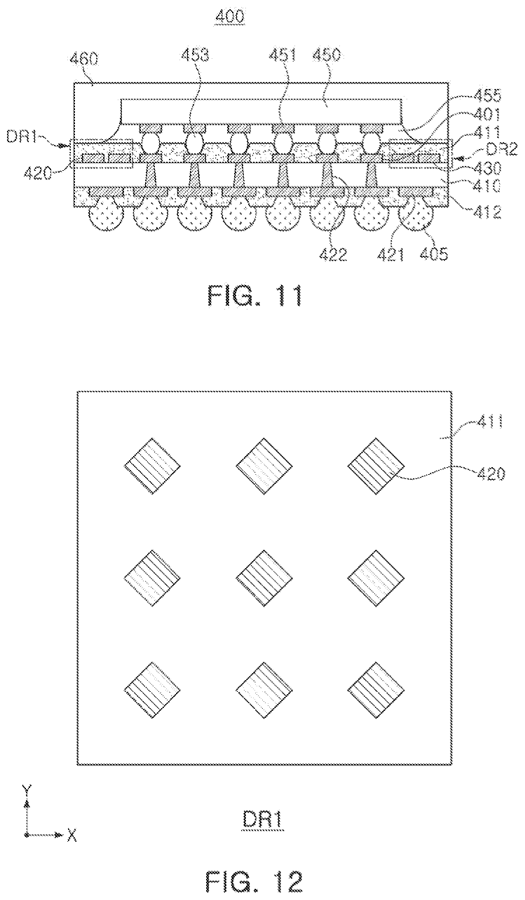

FIG. 11 is a cross-sectional view illustrating a semiconductor package according to an exemplary embodiment of the present inventive concept.

Referring to FIG. 11, a semiconductor package 400 according to an exemplary embodiment of the present inventive concept may include a printed circuit board and a semiconductor chip 450 mounted on the printed circuit board. A plurality of pads 451 may be formed on a lower surface of the semiconductor chip 450, and may be connected to the printed circuit board by microbumps 453. A lower protective layer 455 protecting the microbumps 453 and the plurality of pads 451 may be formed between the semiconductor chip 450 and the printed circuit board. In addition, an upper protective layer 460 may cover an upper surface of the semiconductor chip 450, and the printed circuit board may be formed on the semiconductor chip 450.

The printed circuit board may include a base substrate 410, circuit patterns 421 and 422 formed in the base substrate 410, and conductive dummy patterns 420 and 430 formed in dummy regions DR1 and DR2 to significantly reduce deformation of the printed circuit board. The circuit patterns 421 and 422 may respectively represent a redistribution wiring pattern and a via.

Various circuit patterns may also be further formed.

The vias 422 may connect connection pads 401 connected to the microbumps 453 and the redistribution wiring pattern 421 to each other. The redistribution wiring pattern 421 may be connected to a connection terminal 405 formed on a lower portion of the base substrate 410. Solder resist layers 411 and 412 may be formed on upper and lower surfaces of the base substrate 410, respectively. The solder resist layers 411 and 412 may protect the circuit patterns 421 and 422 and the conductive dummy patterns 420 and 430, and may include a nonconductive material.

The conductive dummy patterns 420 and 430 may be formed in the dummy regions DR1 and DR2. The dummy regions DR1 and DR2 may be regions disposed on the upper and/or lower surface of the base substrate on which the circuit patterns 421 and 422 are not formed. The conductive dummy patterns 420 and 430 may be separately disposed in a lattice form in the dummy regions DR1 and DR2, respectively, and may be separated from boundaries of the dummy regions DR1 and DR2. For example, the conductive dummy patterns 420 and 430 may be respectively surrounded by the first solder resist layer 411 in directions parallel to a plane of an upper surface of the base substrate 410.

According to an exemplary embodiment of the present inventive concept, external forces may occur during manufacture and use of the semiconductor package 400, or heat may be generated in the semiconductor chip 450 and the circuit patterns 421, 422 during operation of the semiconductor package 400. For example, in a case in which the semiconductor package 400 is exposed to heat, force, or the like, the printed circuit board and the semiconductor chip 450 may become distorted, causing breakage of the printed circuit board or the semiconductor chip 450 or damage to the microbumps 453.

The base substrate 410 may include an insulating material and may include, for example, an FR4 material including a glass fiber. The glass fiber included in an FR4 material may have a woven structure, such that the base substrate 410 may have directionally dependent anisotropic properties exhibiting different degrees of rigidity, modulus, thermal expansion coefficients and the like, in different directions parallel to a plane of an upper surface of the base substrate 410. According to an exemplary embodiment of the present inventive concept, the shapes of the conductive dummy patterns 420 and 430 may be determined in consideration of the anisotropic properties of the base substrate 410 as described above in order to compensate for vulnerability to potential warping forces.

The conductive dummy patterns 420 and 430 may be formed in such a manner that maximum lengths thereof in edge directions of the base substrate 410 pass through respective centers of the conductive dummy patterns 420 and 430. For example, shapes of the conductive dummy patterns 420 and 430 satisfying the above conditions may include a cross, a rhombus, a hexagon, an elliptical shape. In addition, another length of each of the conductive dummy patterns 420 and 430, which is not parallel to the edge direction of the base substrate 410 and passing through the center thereof, may be smaller than the maximum length. The shape of the conductive dummy patterns 420 and 430 may be determined according to the above criteria.

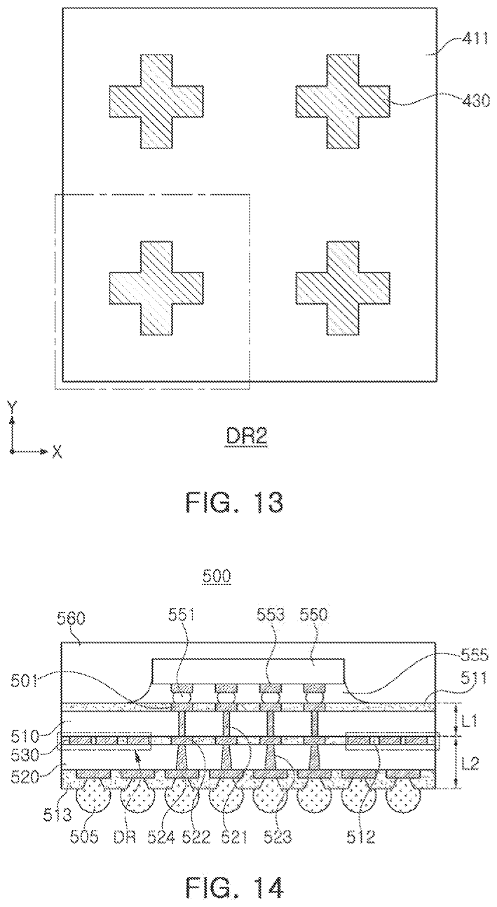

On the other hand, in the conductive dummy patterns 420 and 430 according to an exemplary embodiment of the present inventive concept first conductive dummy patterns 420 included in the first dummy region DR1 and second conductive dummy patterns 430 included in the second dummy region DR2 may have different shapes from one another, which will be described in more detail hereafter with reference to FIGS. 12 and 13.

FIGS. 12 and 13 are enlarged views of the first dummy region DR1 and the second dummy region DR2 of the semiconductor package 400 according to the exemplary embodiment of the present inventive concept illustrated in FIG. 11. The first conductive dummy patterns 420 and the second conductive dummy patterns 430 may include copper (Cu).

Referring to FIG. 12 illustrating the first dummy region DR1, the plurality of first conductive dummy patterns 420 may have a rhombic shape. The plurality of first conductive dummy patterns 420 may be separately disposed in a lattice form in the first dummy region DR1, and may be separated from a boundary of the first dummy region DR1. For example, as illustrated in FIG. 12, the first conductive dummy patterns 420 may be respectively surrounded by the first solder resist layer 411 and may be spaced apart from edges of the dummy region DR1.

As described above, each of the first conductive dummy patterns 420 having a rhombic shape may have a maximum length, in a position parallel to a first direction (e.g., an x-direction) and passing through the center of each of the first conductive dummy patterns 420, and may also have a maximum length in a position parallel to a second direction (e.g., a y-direction) and passing through the center of each of the first conductive dummy patterns 420. In addition, a length that is not parallel to the first direction or the second direction may be not be greater than the maximum length. Thus, deformation due to heat and force generated externally and/or internally of the base substrate 410 (having anisotropic properties) may be significantly reduced.

Next, referring to FIG. 13 illustrating the second dummy region DR2, the plurality of second conductive dummy patterns 430 may have a cross shape. The plurality of second conductive dummy patterns 430 may be disposed in a lattice form in which they are separately arranged, in the second dummy region DR2, and may be separated from a boundary of the second dummy region DR2. Thus, similar to the first conductive dummy patterns 420, each of the second conductive dummy patterns 430 may be at least partially surrounded by the first solder resist layer 411.

Similarly to the first conductive dummy patterns 420, each of the second conductive dummy patterns 430 may include a maximum length in a position, parallel to the first direction (e.g., the x-direction) and passing through the center of each of the second conductive dummy patterns 430. A length that is not parallel to the first direction and the second direction may not be greater than the maximum length. Thus, deformation due to heat and force generated externally and/or internally of the base substrate 410 having anisotropic properties, may be significantly reduced.

Referring to FIGS. 12 and 13, the numbers of the conductive dummy patterns 420 and 430 included in the first dummy region DR1 and the second dummy region DR2 may be different from each other. According to an exemplary embodiment of the present inventive concept, when the numbers of the conductive dummy patterns 420 and 430 are different from each other, respective areas of the first conductive dummy patterns 420 and respective areas of the second conductive dummy patterns 430 may be different from each other. The first dummy region DR1 and the second dummy region DR2 may have copper in the same ratio.

According to an exemplary embodiment of the present inventive concept, when the number of the first conductive dummy patterns 420 is greater than the number of the second conductive dummy patterns 430 as illustrated in FIGS. 12 and 13, the area of each of the second conductive dummy patterns 430 may be larger than the area of each of the first conductive dummy patterns 420. In contrast, when the number of the first conductive dummy patterns 420 is less than the number of the second conductive dummy patterns 430, the area of each of the second conductive dummy patterns 430 may be smaller than the area of each of the first conductive dummy patterns 420. In this case, it may be assumed that a thickness of each of the first conductive dummy patterns 420 and a thickness of each of the second conductive dummy patterns 430 are substantially identical to each other.

FIG. 14 is a cross-sectional view illustrating a semiconductor package according to an exemplary embodiment of the present inventive concept.

According to an exemplary embodiment of the present inventive concept as illustrated in FIG. 14, a semiconductor package 500 may include a printed circuit board and a semiconductor chip 550 mounted thereon. Similarly to the description above with reference to FIG. 11, the semiconductor chip 550 may be mounted on the printed circuit board by a plurality of pads 553 and a plurality of microbumps 551. The microbumps 551 may be protected by a lower protective layer 555, and the semiconductor chip 550 may be covered by an upper protective layer 560 for blocking static electricity, foreign substances and the like.

The printed circuit board may include a plurality of layers L1 and L2. For example, a first layer L1 may include a first base substrate 510, connection pads 501 formed on an upper surface of the first base substrate 510, and first vias 521. A first solder resist layer 511 may be formed on an upper surface of the first base substrate 510, and the first solder resist layer 511 may cover circuit patterns.

A second layer L2 may include a second base substrate 520, a first redistribution wiring pattern 522 and a second redistribution wiring pattern 524 formed on upper and lower surfaces of the second base substrate 520 respectively, and second vias 523. A second solder resist layer 512 and a third solder resist layer 513 may be formed on upper and lower surfaces of the second base substrate 520, respectively. The third solder resist layer 513 exposes a portion of the second redistribution wiring pattern 524, and the second redistribution wiring pattern 524 may be connected to a plurality of connection terminals 505 in a region in which the third solder resist layer 513 is not formed.

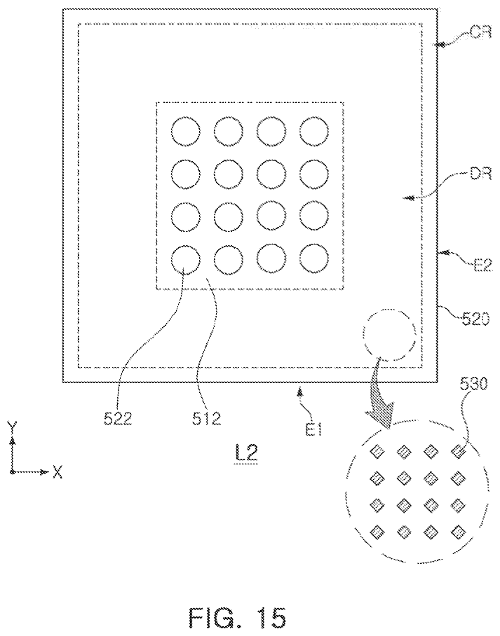

On the other hand, a plurality of conductive dummy patterns 530 may be formed in the second layer L2. The plurality of conductive dummy patterns 530 may be formed in a dummy region DR. According to an exemplary embodiment of the present inventive concept, circuit patterns other than the conductive dummy patterns 530 may not be formed on an upper surface of the second layer L2. For example, on the upper surface of the second layer L2, all the regions other than the first distribution wiring pattern 522 connected to the second via 523 may be provided as the dummy region DR, which will be described below with reference to FIG. 15.

FIG. 15 is a plan view illustrating a portion of layers of a semiconductor package according to an exemplary embodiment of the present inventive concept.

Referring to FIG. 15, an upper surface of the second base substrate 520 included in the second layer L2 may be covered with the second solder resist layer 512. The second solder resist layer 512 may expose the first redistribution wiring pattern 522, and the first redistribution wiring pattern 522 may be electrically connected to circuit patterns formed in the first layer L1 on the second layer L2.

On the other hand, the remaining regions, except for the region in which the first redistribution wiring pattern 522 is formed, may all be provided as the dummy region DR. The plurality of conductive dummy patterns 530 may be formed in the dummy region DR. Referring to FIG. 15, the conductive dummy patterns 530 are illustrated as having a rhombic shape, but may have various shapes such as a cross shape, a hexagon shape, an elliptical shape or the like. The conductive dummy patterns 530 may be at least partially surrounded by the second solder resist layer 512 in the dummy region DR, and may be disposed in a lattice form in which the conductive dummy patterns 530 are separately arranged in a plurality of rows and columns.

The conductive dummy patterns 530 may have a maximum length in a first direction (e.g., a x-direction) parallel to a first edge E1 of the second base substrate 520 or in a second direction (e.g., a y-direction) parallel to a second edge E2 of the base substrate 520. In addition, maximum lengths of the conductive dummy patterns 530 may pass through centers of the conductive dummy patterns 530, respectively. Thus, according to an exemplary embodiment of the present inventive concept, warping may be efficiently reduced in the printed circuit board and the semiconductor package, as well as of the second base substrate 420 formed of an FR4 material having a woven structure and thus having anisotropic properties.

According to the exemplary embodiment of the present inventive concept as illustrated in FIG. 15, the conductive dummy patterns 530 are illustrated as having the same shape and the same area, but the shape of the conductive dummy patterns 530 is not necessarily limited to an identical shape throughout. For example, at least portions of the conductive dummy patterns 530 may have different shapes, or may have different areas. Alternatively, the dummy region DR may be divided into a plurality of regions, and the shapes and areas of the conductive dummy patterns 530 included in the divided regions may be different.

According to an exemplary embodiment of the present inventive concept, the semiconductor package may further include a sub-substrate disposed on the printed circuit board and including a conductive dummy pattern. The sub-substrate only may include the dummy region. An area of the conductive dummy pattern included in the sub-substrate may be larger than an area of the conductive dummy pattern included in the printed circuit board. The number of the conductive dummy patterns included in the sub-substrate may be greater than the number of the conductive dummy patterns included in the printed circuit board. A shape of the conductive dummy pattern included in the sub-substrate may be different from a shape of the conductive dummy pattern included in the printed circuit board.

As set forth above, according to an exemplary embodiment of the present inventive concept, a length of the conductive dummy pattern in a direction parallel to an edge of a base substrate may have a maximum value in a position passing through a center of the conductive dummy pattern. Thus, in the case of a printed circuit board and a semiconductor package, including a base substrate with different structural characteristics in two directions intersecting with each other, warping due to external factors may be reduced.

While exemplary embodiments of the present inventive concept have been shown and described above, it will be understood by one of ordinary skill in the art that variations in form and detail may be made therein without departing from the spirit and scope of the present disclosure as defined by the appended claims.

What is claimed is:

1. A printed circuit board comprising:
a base substrate including a pair of first edges extending in a first direction and a pair of second edges extending in a second direction, perpendicular to the first direction;
a circuit region including a plurality of circuit patterns disposed on at least one of a first surface and a second surface of the base substrate; and
a dummy region including a conductive dummy pattern disposed on at least one of the first surface and the second surface,
wherein the conductive dummy pattern is separated from a boundary of the dummy region, and
wherein a maximum length of the conductive dummy pattern in the first or second direction passes through a center of the conductive dummy pattern.

2. The printed circuit board of claim 1, wherein a maximum length of the conductive dummy pattern in a first direction and the second direction passes the center of the conductive dummy pattern.

3. The printed circuit board of claim 1, wherein the conductive dummy pattern has at least one of a rhombic shape, a cross shape, a hexagonal shape, and an elliptical shape.

4. The printed circuit board of claim 1, wherein the dummy region comprises a plurality of dummy regions,
wherein each of the plurality of dummy regions includes a plurality of the conductive dummy patterns.

5. The printed circuit board of claim 4, wherein in each of the plurality of dummy regions, the plurality of conductive dummy patterns are separated from each other and disposed in a lattice form.

6. The printed circuit board of claim 4, wherein the conductive dummy patterns included in a first portion of the plurality of dummy regions have different shapes or sizes from the conductive dummy patterns included in a second portion of the plurality of dummy regions.

7. The printed circuit board of claim 1, wherein a length of the conductive dummy pattern that is not parallel to the first direction or the second direction and passes through the center of the conductive dummy patterns is smaller than the maximum length.

8. The printed circuit board of claim 1, wherein the conductive dummy pattern includes copper.

9. The printed circuit board of claim 1, wherein the dummy region comprises a solder resist layer formed to at least partially surround the conductive dummy pattern.

10. A semiconductor package comprising:
a printed circuit board including a circuit region having a plurality of circuit patterns, and a dummy region including a conductive dummy pattern separated from the plurality of circuit patterns, the printed circuit board including a first edge extending in a first direction and a second edge extending in a second direction, perpendicular to the first direction; and
a semiconductor chip mounted on the printed circuit board and connected to the plurality of circuit patterns,
wherein the conductive dummy pattern is separated from a boundary between the circuit region and the dummy region, and a maximum length of the conductive dummy pattern in the first direction passes through a center of the conductive dummy pattern.

11. The semiconductor package of claim 10, further comprising:
a sub-substrate disposed on the printed circuit board and including the conductive dummy pattern.

12. The semiconductor package of claim 11, wherein the sub-substrate only includes the dummy region.

13. The semiconductor package of claim 11, wherein an area of the conductive dummy pattern included in the sub-substrate is larger than an area of the conductive dummy pattern included in the printed circuit board.

14. The semiconductor package of claim 11, wherein the number of the conductive dummy patterns included in the sub-substrate is greater than the number of the conductive dummy patterns included in the printed circuit board.

15. The semiconductor package of claim 11, wherein a shape of the conductive dummy pattern included in the sub-substrate is different from a shape of the conductive dummy pattern included in the printed circuit board.

16. The semiconductor package of claim 10, wherein the printed circuit board comprises a base substrate on which the plurality of circuit patterns and the conductive dummy pattern are disposed, and the base substrate is formed of a glass fiber having a woven structure.

17. The semiconductor package of claim 10, wherein the printed circuit board comprises a solder resist layer covering the plurality of circuit patterns, and the solder resist layer separates the plurality of circuit patterns from the conductive dummy pattern.

18. The semiconductor package of claim 10, wherein the conductive dummy pattern has at least one of a rhombic shape, a cross shape, and a hexagonal shape.

19. A semiconductor package comprising:
a printed circuit board including a plurality of circuit patterns and a conductive dummy pattern separated from the plurality of circuit patterns, the conductive dummy pattern having a rhombic shape or a cross shape and being at least partially surrounded by a solder resist layer; and
a semiconductor chip mounted on the printed circuit board and connected to the plurality of circuit patterns,
wherein a length of the conductive dummy pattern in a first direction parallel to an edge of the printed circuit board has a maximum value passing through a center of the conductive dummy pattern.

20. The semiconductor package of claim 19, wherein a length of the conductive dummy pattern in a second direction, perpendicular to the first direction has a maximum value passing through the center of the conductive dummy pattern.
